(19) United States
(12) Patent Application Publication
(10) Pub. No.: US 2025/0167096 A1
(43) Pub. Date: May 22, 2025

(54) INTERCONNECT SUBSTRATE

(71) Applicant: SHINKO ELECTRIC INDUSTRIES CO., LTD., Nagano (JP)

(72) Inventors: Makoto TSUKAHARA, Nagano (JP); Kei MURAYAMA, Nagano (JP); Yoshihiro MACHIDA, Nagano (JP); Hiroshi TANEDA, Nagano (JP); Tatsuki SUMI, Aichi (JP)

(21) Appl. No.: 18/944,453

(22) Filed: Nov. 12, 2024

(30) Foreign Application Priority Data
Nov. 16, 2023 (JP) 2023-194937

(51) Int. Cl. H01L 23/498; H01L 23/66

(52) U.S. Cl. CPC H01L 23/49838; H01L 23/49822; H01L 23/66; H01L 2223/6627

(57) ABSTRACT

An interconnect substrate includes n insulating layers (n≥2), two opposing conductors arranged across the n insulating layers, and first and second post-walls each connecting the two a conductors, wherein post-wall waveguide is constituted at least by the two conductors and the first and second post-walls, which define a zone serving as a transmission path, wherein each of the first and second post-walls includes columnar portions each made by stacking pads and via interconnects penetrating the insulating layers, each pad being positioned between two vertically adjacent via interconnects, the columnar portions being arranged at a predetermined interval along a first direction for transmitting electromagnetic waves, and wherein in each of the first and second post-walls, the pads include two or more connecting pads, each being arranged in contact with an m-th insulating layer (1≤m≤n−1) and connecting two or more via interconnects arrayed along the first direction in the m-th insulating layer.

### CROSS-REFERENCE TO RELATED APPLICATIONS

The present application is based on and claims priority to Japanese Patent Application No. 2023-194937 filed on Nov. 16, 2023, with the Japanese Patent Office, the entire contents of which are incorporated herein by reference.

### FIELD

The disclosures herein relate to interconnect substrates.

### BACKGROUND

A technique known as a post-wall waveguide has been proposed. The post-wall waveguide has, for example, conductor foils formed on the upper and lower surfaces of a dielectric block, opposite-side post walls, and a rear post wall. The opposite-side post walls and the rear post wall are, for example, formed of a plurality of metal posts vertically penetrating the dielectric block, and the upper and lower end surfaces of the metal posts are connected to the conductor foils (For example, see Patent Document 1).

A post wall may alternatively be formed, for example, as a laminated structure of via interconnects and pads by using an interconnect substrate manufacturing technique.

Since the post-wall waveguide is intended for confining electromagnetic waves and not for conducting electricity, the via interconnects and the pads may sometimes have no connection for conducting electricity. In such a case, an electrical conduction check may be difficult to employ in order to detect cracks or breakages which may occur at interfaces between the via interconnects and the pads.

Accordingly, there may be a need to improve connection reliability between the via interconnects and the pads of the post-wall waveguide embedded in an interconnect substrate.

### RELATED-ART DOCUMENT

[Patent document 1] U.S. Pat. No. 5,669,043

### SUMMARY

According to an aspect of the embodiment, an interconnect substrate includes n insulating layers (n is a natural number greater than or equal to 2), two conductors arranged in opposition to each other across the n insulating layers, and a first post wall and a second post wall each connecting the two conductors, wherein a post-wall waveguide is constituted at least by the two conductors, the first post wall, and the second post wall, which surround and define a zone that serves as an electromagnetic wave transmission path, wherein each of the first post wall and the second post wall includes columnar portions each of which is made by stacking pads and respective via interconnects penetrating the insulating layers, each of the pads being positioned between two vertically adjacent ones of the via interconnects, the columnar portions being arranged at a predetermined interval along a first direction for transmitting electromagnetic waves, and wherein in each of the first post wall and the second post wall, the pads include two or more connecting pads, each of which is arranged in contact with an m-th one of the insulating layers (m is a natural number from 1 to n−1) and connects two or more of the via interconnects arrayed along the first direction in the m-th one of the insulating layers.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are plan views illustrating an example of an interconnect substrate according to a first embodiment;

FIGS. 2A and 2B are cross-sectional views illustrating the example of the interconnect substrate according to the first embodiment;

FIGS. 3A through 3D are drawings illustrating an example of a manufacturing sequence of the interconnect substrate according to the first embodiment;

FIGS. 4A and 4B are drawings illustrating an example of an interconnect substrate according to a first variation of the first embodiment;

FIGS. 5A and 5B are drawings illustrating an example of an interconnect substrate according to a second variation of the first embodiment;

FIGS. 6A and 6B are drawings illustrating an example of an interconnect substrate according to a third variation of the first embodiment;

FIGS. 7A and 7B are drawings illustrating an example of an interconnect substrate according to a fourth variation of the first embodiment; and

FIGS. 8A and 8B are drawings illustrating a simulation.

### DESCRIPTION OF EMBODIMENTS

In the following, an embodiment of the invention will be described with reference to the accompanying drawings. In these drawings, the same components are referred to by the same reference numerals, and duplicate descriptions thereof may be omitted.

### First Embodiment

### Overall Structure of Interconnect Substrate

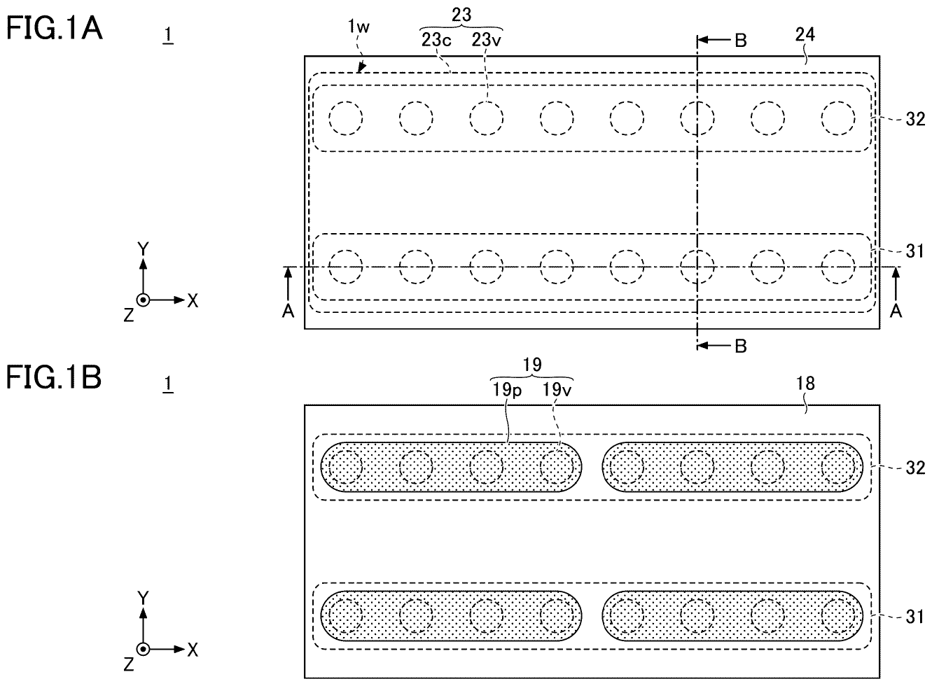

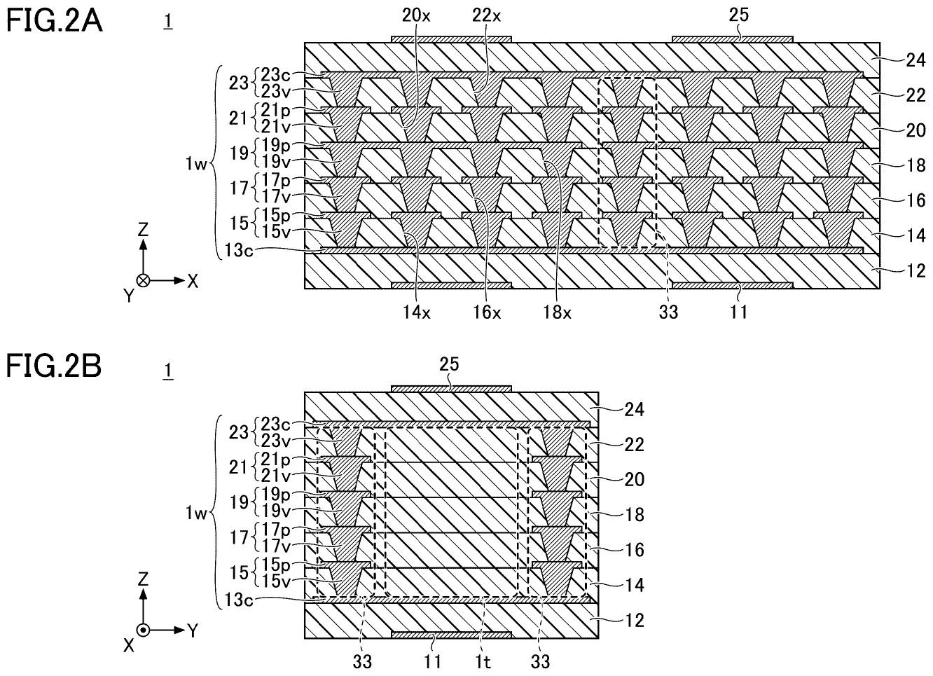

FIGS. 1A and 1B are plan views illustrating an example of an interconnect substrate according to a first embodiment. FIG. 1A is a view of an insulating layer 24 and the underlying layer illustrated in FIGS. 2A and 2B, and FIG. 1B is a view of an interconnect layer 19 and the underlying layer illustrated in FIGS. 2A and 2B. FIGS. 2A and 2B are cross-sectional views illustrating an example of the interconnect substrate according to the first embodiment. FIG. 2A is a cross-sectional view taken along the line A-A in FIG. 1A, and FIG. 2B is a cross-sectional view taken along the line B-B in FIG. 1A.

In each of the accompanying drawings, an X axis, a Y axis, and a Z axis orthogonal to each other are shown as necessary for reference. The direction parallel to the X axis is referred to as the X direction, and the direction parallel to the Y axis is referred to as the Y direction, with the direction parallel to the Z axis being referred to as the Z direction. It may be noted that these illustrated directions do not limit the orientation in which the interconnect substrate 1 is placed when used.

Referring to FIGS. 1A and 1B and FIGS. 2A and 2B, the interconnect substrate 1 includes an interconnect layer 11, an insulating layer 12, a conductor 13c, an insulating layer 14, an interconnect layer 15, an insulating layer 16, an interconnect layer 17, an insulating layer 18, an interconnect layer 19, an insulating layer 20, an interconnect layer 21, an insulating layer 22, an interconnect layer 23, an insulating layer 24, and an interconnect layer 25. The interconnect substrate 1 may further include a solder resist layer on the insulating layer 24, which selectively exposes the interconnect layer 25. The interconnect substrate 1 has a post-wall waveguide 1w embedded therein. The post-wall waveguide 1w will be described later.

In the present embodiment, for the sake of convenience, the interconnect layer 25 side of the interconnect substrate 1 in FIGS. 2A and 2B is referred to as an upper side or a first side, and the interconnect layer 11 side is referred to as a lower side or a second side. The surface of a member toward the interconnect layer 25 side is referred to as a first surface or an upper surface, and the surface of the member on the interconnect layer 11 side is referred to as a second surface or a lower surface. It may be noted, however, that the interconnect substrate 1 may be used upside down or may be arranged at any angle. A plan view refers to the view of an object as seen from the direction normal to the first surface of the insulating layer 24, and a plane shape refers to the shape of an object as seen from the direction normal to the first surface of the insulating layer 24.

In the example illustrated in FIGS. 1A and 1B and FIGS. 2A and 2B, the plane shape of the interconnect substrate 1 is rectangular, and the interconnect substrate 1 has two sides parallel to the X direction and two sides parallel to the Y direction in plan view. The thickness direction of the interconnect substrate 1 is in the Z direction.

In the interconnect substrate 1, the interconnect layer 11 is embedded in the lower surface of the insulating layer 12. The lower surface of the interconnect layer 11 is exposed at the lower surface of the insulating layer 12, and the upper surface and the side surfaces of the interconnect layer 11 are covered with the insulating layer 12. The material of the interconnect layer 11 may be, for example, copper (Cu) or the like. The interconnect layer 11 may be allowed to have a laminated structure of a plurality of metal layers. The thickness of the interconnect layer 11 may be, for example, about 10 to 30 μm.

The insulating layer 12 is formed to cover the side surfaces and the upper surfaces of the interconnect layer 11. The lower surface of the insulating layer 12 may be flush with the lower surface of the interconnect layer 11, for example. The material of the insulating layer 12 may be, for example, an insulating resin mainly composed of an epoxy-based resin or a polyimide-based resin. The thickness of the insulating layer 12 may be, for example, about 20 to 40 μm. Here, the thickness of the insulating layer 12 is defined as a distance from the upper surface of the interconnect layer 11 to the upper surface of the insulating layer 12. The same applies to the thicknesses of the other insulating layers. The insulating layer 12 can contain a filler such as silica (SiO₂).

The conductor 13c is a solid pattern formed on the upper surface of the insulating layer 12. The conductor 13c is, for example, rectangular in plan view. The material and the thickness of the conductor 13c may be, for example, the same as those of the interconnect layer 11.

The insulating layer 14 is disposed on the upper surface of the insulating layer 12 and covers the upper surface and the side surfaces of the conductor 13c. The material and the thickness of the insulating layer 14 may be, for example, the same as those of the insulating layer 12. The insulating layer 14 can contain a filler such as silica (SiO₂).

The interconnect layer 15 includes via interconnects 15v filling via holes 14x that penetrate the insulating layer 14 and reach the upper surface of the conductor 13c, and pads 15p formed on the upper surface of the insulating layer 14. The via interconnects 15v may each have an inverted truncated cone shape whose diameter is larger on the interconnect layer 17 side than on the conductor 13c side. For example, the diameter on the interconnect layer 17 side may be about 70 μm, and the diameter on the conductor 13c side may be about 50 μm. The interconnect layer 15 is electrically connected to the conductor 13c situated at the bottoms of the via holes 14x. The material of the interconnect layer 15 and the thickness of the pads 15p may be, for example, the same as those of the interconnect layer 11.

The insulating layer 16 is disposed on the upper surface of the insulating layer 14 and covers the upper surface and the side surfaces of the pads 15p of the interconnect layer 15. The material and the thickness of the insulating layer 16 may be, for example, the same as those of the insulating layer 12. The insulating layer 16 can contain a filler such as silica (SiO₂).

The interconnect layer 17 includes via interconnects 17v filling via holes 16x that penetrate the insulating layer 16 and reach the upper surface of the pads 15p of the interconnect layer 15, and pads 17p formed on the upper surface of the insulating layer 16. The via interconnects 17v may each have an inverted truncated cone shape whose diameter is larger on the interconnect layer 19 side than on the interconnect layer 15 side. The interconnect layer 17 is electrically connected to the interconnect layer 15 situated at the bottoms of the via holes 16x. The material of the interconnect layer 17 and the thickness of the pads 17p may be, for example, the same as those of the interconnect layer 11.

The insulating layer 18 is disposed on the upper surface of the insulating layer 16 and covers the upper surface and the side surfaces of the pads 17p of the interconnect layer 17. The material and the thickness of the insulating layer 18 may be, for example, the same as those of the insulating layer 12. The insulating layer 18 can contain a filler such as silica (SiO₂).

The interconnect layer includes via interconnects 19v filling via holes 18x that penetrate the insulating layer 18 and reach the upper surfaces of the pads 17p of the interconnect layer 17, and pads 19p formed on the upper surface of the insulating layer 18. The via interconnects 19v may each have an inverted truncated cone shape whose diameter is larger on the interconnect layer 21 side than on the interconnect layer 17 side. The interconnect layer 19 is electrically connected to the interconnect layer 17 situated at the bottoms of the via holes 18x. The material of the interconnect layer 19 and the thickness of the pads 19p may be, for example, the same as those of the interconnect layer 11.

The insulating layer 20 is disposed on the upper surface of the insulating layer 18 and covers the upper surface and the side surfaces of the pads 19p of the interconnect layer 19. The material and the thickness of the insulating layer 20 may be, for example, the same as those of the insulating layer 12. The insulating layer 20 can contain a filler such as silica (SiO₂).

The interconnect layer 21 includes via interconnects 21v filling via holes 20x that penetrate the insulating layer 20 and reach the upper surfaces of the pads 19p of the interconnect layer 19, and pads 21p formed on the upper surface of the insulating layer 20. The via interconnects 21v may each have an inverted truncated cone shape whose diameter is larger on the interconnect layer 23 side than on the interconnect layer 19 side. The interconnect layer 21 is electrically connected to the interconnect layer 19 situated at the bottoms of the via holes 20x. The material of the interconnect layer 21 and the thickness of the pads 21p may be, for example, the same as those of the interconnect layer 11.

The insulating layer 22 is disposed on the upper surface of the insulating layer 20 and covers the upper surface and the side surfaces of the pads 21p of the interconnect layer 21. The material and the thickness of the insulating layer 22 may be the same as those of the insulating layer 12, for example. The insulating layer 22 can contain a filler such as silica (SiO₂).

The interconnect layer 23 includes via interconnects 23v filling via holes 22x that penetrate the insulating layer 22 and reach the upper surfaces of the pads 21p of the interconnect layer 21, and a conductor 23c formed on the upper surface of the insulating layer 22. The via interconnects 23v may each have an inverted truncated cone shape whose diameter is larger on the interconnect layer 25 side than on the interconnect layer 21 side. The conductor 23c has a solid pattern. The conductor 23c has, for example, a rectangular shape in plan view. The shape and area of the conductor 23c are, for example, the same as those of the conductor 13c. The interconnect layer 23 is electrically connected to the interconnect layer 21 situated at the bottoms of the via holes 22x. The material of the interconnect layer 23 and the thickness of the conductor 23c may be, for example, the same as that of the interconnect layer 11.

### Post-Wall Waveguide

As illustrated in FIGS. 1A and 1B and FIGS. 2A and 2B, the interconnect substrate 1 includes the post-wall waveguide 1w in which the two conductors 13c and 23c facing each other in the Z direction and both a first post wall 31 and a second post wall 32 connecting the conductor 13c and the conductor 23c surround and define a zone that serves as an electromagnetic wave transmission path 1t. In the example illustrated in FIGS. 1A and 1B and FIGS. 2A and 2B, electromagnetic waves propagate in the X direction. It may be noted that the transmission path It is not limited to a linear shape, but may be curved, or may include both linear and curved sections.

The two conductors of the interconnect substrate according to the present invention are disposed in opposition to each other across insulating layers (n is a natural number greater than or equal to 2). The first post wall and the second post wall are configured such that columnar portions are each formed by stacking the via interconnects passing through the respective insulating layers and the pads positioned between the vertically adjacent via interconnects, and are arranged at a predetermined interval in the X direction for transmitting electromagnetic waves.

In the example of the interconnect substrate 1 illustrated in FIGS. 1A and 1B and FIGS. 2A and 2B, n is equal to 5, and the conductor 23c is arranged in opposition to the conductor 13c across the insulating layers 14, 16, 18, 20, and 22. The columnar portions 33 are each configured by stacking the via interconnect 15v, the pad 15p, the via interconnect 17v, the pad 17p, the via interconnect 19v, the pad 19p, the via interconnect 21v, the pad 21p, and the via interconnect 23v in this order.

The first post wall 31 and the second post 32 wall face each other across a predetermined distance in the Y direction. The interval between the first post wall 31 and the second post wall 32 in the Y direction (the distance in the Y direction between the central axes of the via interconnects located opposite each other in the Y direction) may be set to, for example, 0.82 mm. The length of each of the first post wall 31 and the second post wall 32 in the X direction may be set to, for example, 5 mm.

In each of the first post wall 31 and the second post wall 32, the central axes of the via interconnects 15v, 17v, 19v, 21v, and 23v constituting the columnar portion 33 substantially coincide with each other. The pitch of the columnar portions 33 in the X direction (the distance in the X direction between the central axes of the via interconnects adjacent in the X direction) may be set to, for example, 0.125 mm. The frequency of an electromagnetic wave that can propagate through the transmission path 1t may be, for example, 150 GHz to 160 GHz.

In each of the first post wall and the second post wall of the interconnect substrate according to the present invention, the pads include at least two connecting pads each of which is disposed in contact with the m-th insulating layer (m is a natural number from 1 to n−1) and connects two or more via interconnects arrayed along the X-direction in the m-th insulating layer. In the m-th insulating layer, each via interconnect is preferably connected to one of the connecting pads.

In the example of the interconnect substrate 1 illustrated in FIGS. 1A and 1B and FIGS. 2A and 2B, m is equal to 3. That is, in each of the first post wall 31 and the second post wall 32 of the interconnect substrate 1, the pads of the interconnect substrate 1 include two connecting pads each of which is disposed in contact with the third insulating layer 18 located between the conductor 13c and the conductor 23c and connects four via interconnects 19v arrayed along the X-direction in the insulating layer 18. The four pads 19p illustrated in dot shading in FIG. 1B are the connecting pads. The width (in Y direction) of the connecting pads may be, for example, 100 to 120 μm.

It should be noted that the interconnect substrate 1 may not have any insulating layer or interconnect layer other than those constituting the post-wall waveguide 1w. That is, the interconnect substrate 1 itself may be the post-wall waveguide 1w.

The interconnect substrate 1 may also have a semiconductor chip mounted or embedded therein. This semiconductor chip may transmit and/or receive, for example, electromagnetic waves transmitted by the transmission path 1t.

As described above, the interconnect substrate 1 includes, in each of the first post wall 31 and the second post wall 32, two or more connecting pads each of which is arranged in contact with at least one insulating layer and connects two or more via interconnects arrayed in this insulating layer along the X direction in which electromagnetic waves are transmitted. As a result, the following advantageous effects are obtained.

That is, if stress were applied, In the absence of the connecting pads, to the interface between the bottom surfaces of the via interconnects and the top surfaces of the pads, cracks would be likely to occur. In some cases, the cracks would grow longer, resulting in breakages. In contrast, with the connecting pads being provided as in the interconnect substrate 1, stress is dispersed by the connecting pads, so that cracks are less likely to occur. When the connecting pads are present, the area of the interface between the pads and the insulating layer is increased as compared with when the connecting pads are not present. This creates an anchoring effect, which increases the connection strength between the via interconnects and the pads.

As a result, the connection reliability between the via interconnects and the pads is effectively improved in the post-wall waveguide 1w embedded in the interconnect substrate 1. That is, the first post wall and the second post wall, for which detecting defects electrically is difficult, has effectively improved structural strength, which improves the reliability of the interconnect substrate 1 as a whole.

In the interconnect substrate 1, each via interconnect in the third insulating layer 18 is connected to one of the connecting pads. That is, there is no isolated via interconnect that is not connected to an adjacent via interconnect in the third insulating layer 18. Thus, the above-noted effect is further effectively enhanced.

If only one connecting pad for connecting two or more via interconnects arrayed along the X direction in which electromagnetic waves propagate were provided in one insulating layer in each of the first post wall and the second post wall, breakage would be likely to occur due to a difference in the amount of extension caused by a difference in the thermal expansion coefficient between the connecting pad and the resin. This would be especially so when the length of the connecting pad was long. It is thus not preferable to provide only one connecting pad in one insulating layer in each of the first post wall and the second post wall.

### Method of Making Interconnect Substrate

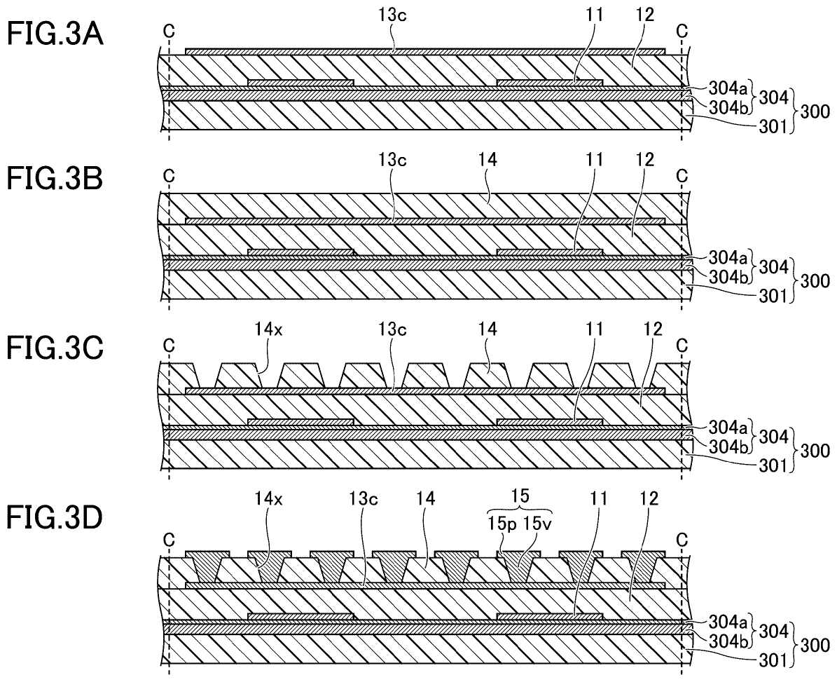

In the following, a method of making the interconnect substrate according to the first embodiment will be described. FIGS. 3A through 3D are drawings illustrating an example of the manufacturing sequence of the interconnect substrate according to the first embodiment. Although an example of the manufacturing sequence that forms a layer structure only on the first side of a support is illustrated here, a layer structure may alternatively be formed on both the first and second sides of the support. Broken lines C in each drawing indicate positions where the interconnect substrate is cut for singulation. The region located between the adjacent broken lines C in the cross-sectional view becomes a single interconnect substrate in the end by singulation.

First, in the step illustrated in FIG. 3A, a support 300 is prepared, and the interconnect layer 11, the insulating layer 12, and the conductor 13c are sequentially laminated on the support 300. The support 300 is made by, for example, laminating a copper foil 304 with a carrier on the first side of a core substrate 301. The core substrate 301 is, for example, a resin substrate having a thickness of about 0.7 mm, and may include a reinforcing member such as a glass fiber. The copper foil 304 with a carrier has a structure in which a thin foil 304a of, for example, copper having a thickness of about 1.5 to 5 μm is detachably bonded on a thick foil (carrier foil) 304b of, for example, copper having a thickness of about 10 to 50 μm, with a release layer (not shown) disposed therebetween. The thick foil 304b is provided as a supporting member for facilitating the handling of the thin foil 304a.

The above-noted structure of the support 300 is only an example, and is not intended to be limiting. For example, a laminate of a plurality of prepregs may be used in place of the core substrate 301 in the support 300. The support 300 may alternatively have a structure in which a copper foil 304 with a carrier is disposed on the first side of a glass substrate, a metal substrate, or the like with a release layer therebetween.

In order to form the interconnect layer 11 on the support 300, for example, a resist layer having an opening at a portion for forming the interconnect layer 11 is formed on the upper surface of the copper foil 304 with a carrier (i.e., the upper surface of the thin foil 304a) by using a dry film resist or the like. Then, the interconnect layer 11 is formed as an electroplating layer on the upper surface of the copper foil 304 with a carrier exposed in the opening by an electroplating method using the copper foil 304 with a carrier as a feeding metal layer. The material and the thickness of the interconnect layer 11 are as described earlier. The resist layer is then peeled off for removal.

In order to form the insulating layer 12, for example, an insulating resin film in a semi-cured state composed mainly of a thermosetting resin is prepared. This insulating resin film is laminated on the upper surface of the copper foil 304 with a carrier and cured by heat and pressure, thereby becoming the insulating layer 12. Alternatively, instead of laminating the insulating resin film, an insulating resin in liquid or paste form may be applied and cured to form the insulating layer 12. The material and the thickness of the insulating layer 12 are as described earlier. The conductor 13c may be formed by any type of interconnect forming method such as a subtractive method or a semi-additive method. The shape, material, and thickness of the conductor 13c are as described earlier.

In the step illustrated in FIG. 3B, the insulating layer 14 covering the conductor 13c is formed on the upper surface of the insulating layer 12. The insulating layer 14 may be formed, for example, by the same method as the insulating layer 12. The material and the thickness of the insulating layer 14 are as described earlier.

In the step illustrated in FIG. 3C, the via holes 14x which penetrate the insulating layer 14 and expose the upper surface of the conductor 13c are formed in the insulating layer 14. The via holes 14x may be formed, for example, by a laser processing method using a CO₂ laser, a YAG laser, an excimer laser, or the like. After the via holes 14x are formed, a desmearing process is preferably performed to remove resin residues adhering to the surface of the conductor 13c exposed at the bottoms of the via holes 14x.

In the step illustrated in FIG. 3D, the interconnect layer 15 is formed on the insulating layer 14. The interconnect layer 15 may be formed by, for example, a semi-additive method. As a specific example, a seed layer for continuously covering the upper surface of the insulating layer 14, the inner surfaces of the via holes 14x, and the upper surface of the conductor 13c exposed in the via holes 14x is formed by electroless plating of copper or sputtering of copper. Thereafter, a resist layer having openings matching the shape of the interconnect layer 15 is formed on the seed layer. An electroplating layer is then formed on the seed layer exposed in these openings by an electroplating method using the seed layer as a feeding layer. After the resist layer is removed, the layer exposed seed from the electroplating layer is removed by etching, which results in the formation of the interconnect layer 15 having the electroplating layer laminated on the seed layer. The interconnect layer 15 includes the via interconnects 15v filling the via holes 14x and the pads 15p formed on the upper surface of the insulating layer 14.

Subsequently the same steps as those illustrated in FIGS. 3B to 3D are repeatedly performed, thereby sequentially forming the insulating layer 16, the via holes 16x, the interconnect layer 17, the insulating layer 18, the via holes 18x, the interconnect layer 19, the insulating layer 20, the via holes 20x, the interconnect layer 21, the insulating layer the via holes 22x, and the interconnect layer 23. Further, the insulating layer 24 and the interconnect layer 25 are formed in substantially the same manner as in FIG. 3A.

After the above process, the support 300 is removed. In order to remove the support 300, first, the core substrate 301 and the thick foil 304b are mechanically peeled off from the thin foil 304a. Next, the thin foil 304a is removed by wet etching using, for example, an aqueous ferric chloride solution, an aqueous cupric chloride solution, an aqueous ammonium persulfate solution, or the like. Then, cutting is indicated by the broken performed at the portions lines C to obtain the individual interconnect substrate 1.

### Variations of First Embodiment

Variations of the first embodiment are directed to examples of an interconnect substrate having connecting pads with different configurations. In connection with the variations of the first embodiment, descriptions of the same components as those of the embodiment described above may be omitted.

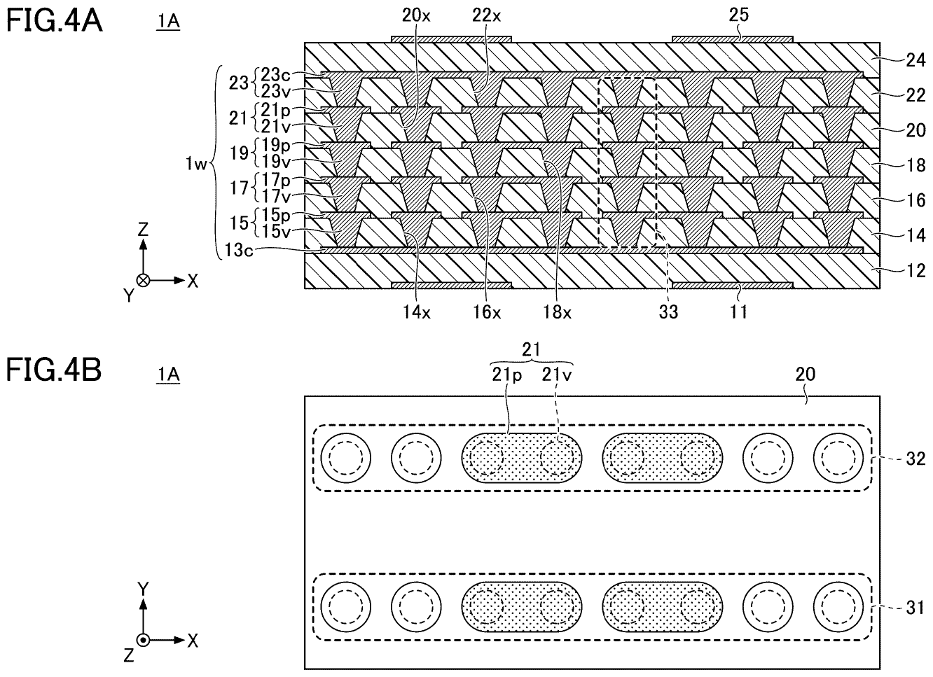

FIGS. 4A and 4B are drawings illustrating an example of the interconnect substrate according to a first variation of the first embodiment. FIG. 4A is a cross-sectional view corresponding to FIG. 2A, and FIG. 4B is a plan view of the interconnect layer 21 and the underlying layer in FIG. 4A. The plan view of the interconnect layer 19 and the underlying layer, the plan view of the interconnect layer 17 and the underlying layer, and the plan view of the interconnect layer 15 and the underlying layer are the same as in FIG. 4B.

In the example of an interconnect substrate 1A illustrated in FIGS. 4A and 4B, for each insulating layer of the first to n−1-th insulating layers, the pads of the interconnect substrate 1A include two or more connecting pads each of which is disposed in contact with the insulating layer and connects two or more via interconnects arrayed along the X direction in the insulating layer. Here, n is equal to 5.

That is, in each of the first post walls 31 and the second post walls 32 of the interconnect substrate 1A, the pads of the interconnect substrate 1A include two connecting pads each of which is arranged in contact with the first insulating layer 14 located between the conductor 13c and the conductor 23c, and connects two via interconnects arrayed along the X direction in the insulating layer 14. Further included are two connecting pads each of which is arranged in contact with the second insulating layer 16 located between the conductor 13c and the conductor 23c, and connects two via interconnects arrayed along the X direction in the insulating layer 16. Further included are two connecting pads each of which is arranged in contact with the third insulating layer 18 located between the conductor 13c and the conductor 23c, and connects two via interconnects arrayed along the X direction in the insulating layer 18. Further included are two connecting pads each of which is arranged in contact with the fourth insulating layer 20 located between the conductor 13c and the conductor 23c, and connects two via interconnects arrayed along the X direction in the insulating layer 20.

The two connecting pads arranged in one insulating layer may be arranged at positions overlapping the two connecting pads in another insulating layer in plan view. In other words, the connecting pads disposed in the insulating layers may be arranged in horizontal rows and vertical columns in the cross-sectional view. In the example illustrated in FIG. 4A, the connecting pads are arranged in four rows and two columns in the cross-sectional view. The number of connecting pads arranged in each insulating layer may also be three or more. Part or all of the connecting pads may each be connected with three or more via interconnects.

As described above, the interconnect substrate 1A includes two or more connecting pads each of which is arranged in contact with a corresponding insulating layer located between the conductors 13c and 23c and connects two or more via interconnects arrayed along the X direction for transmitting electromagnetic waves in the corresponding insulating layer.

With this arrangement, the effects of dispersing stress through the connecting pads and increasing the connection strength between the via interconnects and the pads due to the anchor effect are further enhanced than those of the interconnect substrate 1. In the post-wall waveguide 1w embedded in the interconnect substrate 1A, thus, the connection reliability between the via interconnects and the pads are further improved than in the interconnect substrate 1.

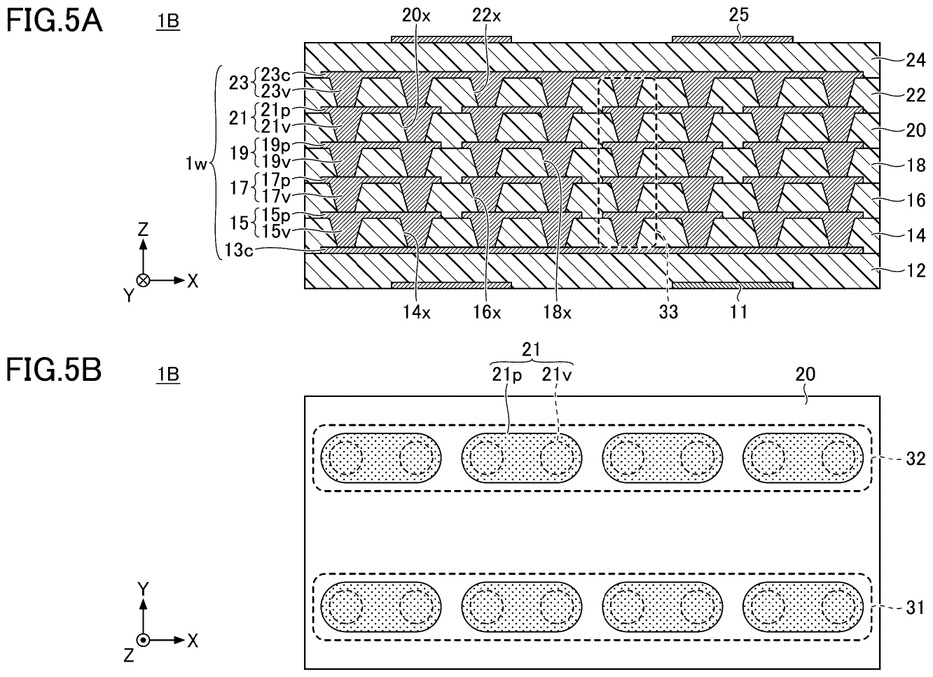

FIGS. 5A and 5B are drawings illustrating an example of the interconnect substrate according to a second variation of the first embodiment. FIG. 5A is a cross-sectional view corresponding to FIG. 2A, and FIG. 5B is a plan view of the interconnect layer 21 and the underlying layer in FIG. 5A. The plan view of the interconnect layer 19 and the underlying lay, the plan view of the interconnect layer 17 and the underlying layer, and the plan view of the interconnect layer 15 and the underlying layer are substantially the same as in FIG. 5B.

In the example of an interconnect substrate 1B illustrated in FIGS. 5A and 5B, the pads of the interconnect substrate 1B in each of the first post wall 31 and the second post wall 32 include four connecting pads each of which is arranged in contact with a corresponding insulating layer located between the conductors 13c and 23c, and connects two via interconnects arrayed along the X direction for transmitting electromagnetic waves in the corresponding insulating layer. In the example illustrated in FIG. 5A, the connecting pads are arranged in four rows and four columns in the cross-sectional view. In the interconnect substrate 1B, each via interconnect in each insulating layer is connected to one of the connecting pads. That is, the interconnect substrate 1B has no isolated via interconnect which is not connected to an adjacent via interconnects.

With this arrangement, the effects of dispersing stress through the connecting pads and increasing the connection strength between the via interconnects and the pads due to the anchor effect are further enhanced than those of the interconnect substrate 1A. In the post-wall waveguide 1w embedded in the interconnect substrate 1B, thus, the connection reliability between the via interconnects and the pads is further improved than in the interconnect substrate 1A.

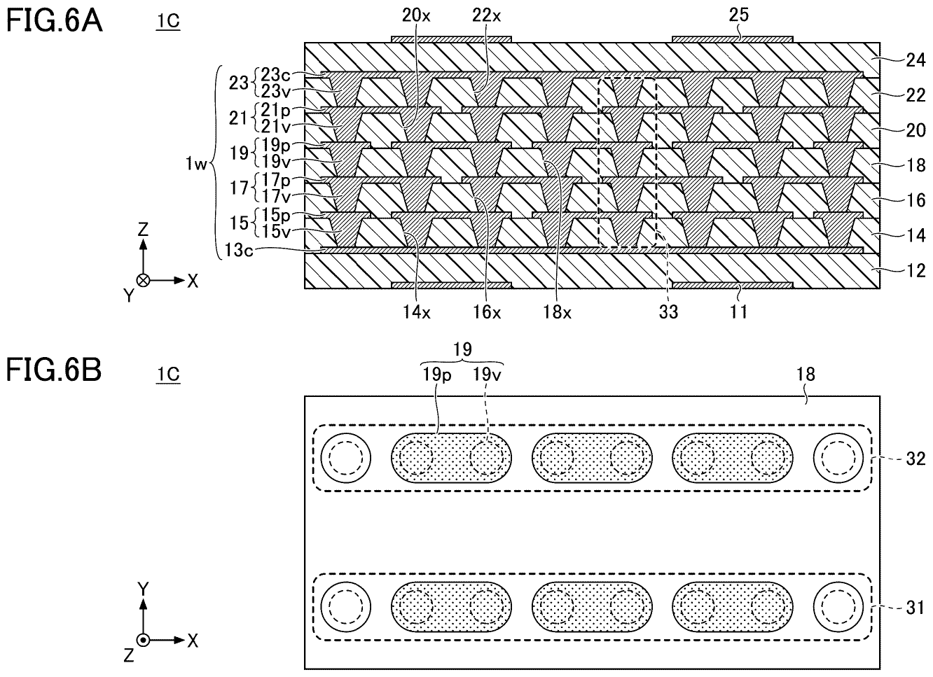

FIGS. 6A and 6B are views illustrating an example of the interconnect substrate according to a third variation of the first embodiment. FIG. 6A is a cross-sectional view corresponding to FIG. 2A, and FIG. 6B is a plan view of the interconnect layer 19 and the underlying layer in FIG. 6A. The plan view of the interconnect layer 15 and the underlying layer is the same as that illustrated in FIG. 6B. The plan view of the interconnect layer 21 and the underlying layer as well as the plan view of the interconnect layer 17 and the underlying layer are the same as in FIG. 5B.

In the example of an interconnect substrate 1C illustrated in FIGS. 6A and 6B, the pads of the interconnect substrate 1C in each of the first post wall 31 and the second post wall 32 include three or four connecting pads each of which is arranged in contact with a corresponding insulating layer positioned between the conductors 13c and 23c, and connects two via interconnects arrayed along the X direction for transmitting electromagnetic waves in the corresponding insulating layer. In the example illustrated in FIG. 6A, the connecting pads are arranged in a staggered manner in a cross-sectional view. The interconnect substrate 1C may have via interconnects that are not connected to an adjacent via interconnect. It may also suffice for two or more connecting pads to be arranged in each insulating layer. A part or all of the connecting pads may each be connected with three or more via interconnects.

As described above, the connecting pads may be arranged in a staggered manner in the cross-sectional view. With this arrangement also, the effects of dispersing stress through the connecting pads and increasing the connection strength between the via interconnects and the pads due to the anchor effect are further enhanced than in the interconnect substrate 1. In the post-wall waveguide 1w embedded in the interconnect substrate 1C, thus, the connection reliability between the via interconnects and the pads are further improved than in the interconnect substrate 1.

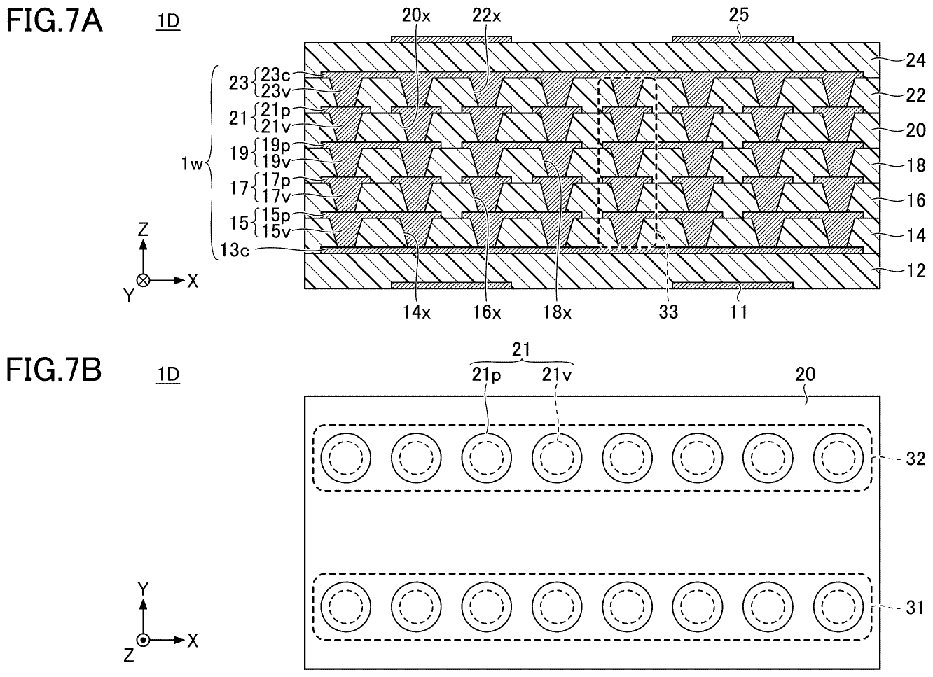

FIGS. 7A and 7B are drawings illustrating an example of the interconnect substrate according to a fourth variation of the first embodiment. FIG. 7A is a sectional view corresponding to FIG. 2A, and FIG. 7B is a plan view of the interconnect layer 21 and the underlying layer in FIG. 7A. The plan view of the interconnect layer 17 and the underlying layer is the same as in FIG. 7B. The plan view of the interconnect layer 19 and the underlying layer as well as the plan view of the interconnect layer 15 and the underlying layer are the same as in FIG. 5B.

In the example of an interconnect substrate 1D illustrated in FIGS. 7A and 7B, insulating layers (i.e., insulating layers 16 and 20) in which all the via interconnects arrayed along the X direction for transmitting electromagnetic waves are isolated and insulating layers (i.e., insulating layers 14 and 18) including two or more connecting pads are alternately laminated. It may suffice for two or more connecting pads to be arranged in each of the insulating layers 14 and 18. Further, part or all of the connecting pads arranged in the insulating layers 14 and 18 may each be connected with three or more via interconnects.

As described above, the interconnect substrate may have an insulating layer in which all via interconnects arrayed along the X direction for transmitting electromagnetic waves are isolated. With this arrangement also, the effects of dispersing stress through the connecting pads and increasing the connection strength between the via interconnects and the pads due to the anchor effect are further enhanced than in the interconnect substrate 1. Accordingly, the connection reliability between the via interconnects and the pads is further improved in the post-wall waveguide 1w embedded in the interconnect substrate 1D than in the interconnect substrate 1.

### Simulation

Focusing on plastic strain as one index for confirming the connection reliability between via interconnects and pads, plastic-strain simulation based on nonlinear static analysis using Abaqus 2021 was carried out with respect to the interconnect substrates of a comparative example, a first working example, and a second working example. Specifically, the stress-free temperature was set to 210° C., and the analysis temperature was set to 25° C. The maximum values of plastic strain generated in the via interconnects and the pads were obtained by simulation.

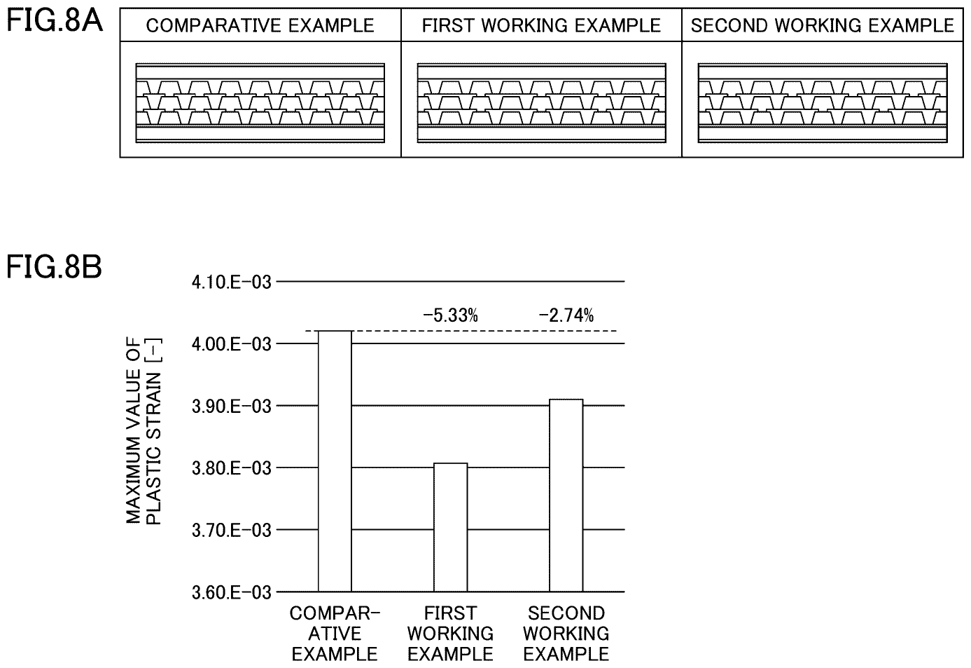

The substrates the interconnect of comparative example, the first working example, and the second working example were all rectangles with dimensions 1.37 mm by 1.37 mm in plan view. As illustrated in FIG. 8A, the insulating layers located between the opposing conductors of each interconnect substrate were 3 layers. The interconnect substrate of the comparative example did not have any connecting pads. The interconnect substrate of the first working example had a structure corresponding to FIG. 5A, in which the connecting pads for connecting two adjacent via interconnects were arranged in a two-dimensional matrix of 2 rows and 4 columns, and there were no isolated via interconnects. The interconnect substrate of the second working example had a structure corresponding to FIG. 6A, in which the connecting pads for connecting two adjacent via interconnects were arranged in a staggered manner, and there were isolated via interconnects.

As illustrated in FIG. 8B, as a result of simulation of plastic strain, the maximum value of plastic strain was reduced by 5.33% in the interconnect substrate of the first working example, compared to the interconnect substrate of the comparative example. In addition, the maximum value of plastic strain was reduced by 2.74% in the interconnect substrate of the second working example, compared to the interconnect substrate of the comparative example.

That is, it was confirmed that the plastic strain can be reduced and the connection reliability between the via interconnects and the pads can be improved by providing the connecting pads in an interconnect substrate as compared with the case where no connecting pads are provided. It is expected that the structure other than the first and second examples, if at least one connecting pad is provided, will have a certain effect in reducing the plastic strain as compared with the case where no connecting pads are provided.

According to at least one embodiment, it is possible to improve connection reliability between the via interconnects and the pads of the post-wall waveguide embedded in an interconnect substrate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An interconnect substrate comprising:
n insulating layers (n is a natural number greater than or equal to 2);
two conductors arranged in opposition to each other across the n insulating layers; and
a first post wall and a second post wall each connecting the two conductors,
wherein a post-wall waveguide is constituted at least by the two conductors, the first post wall, and the second post wall, which surround and define a zone that serves as an electromagnetic wave transmission path,
wherein each of the first post wall and the second post wall includes columnar portions each of which is made by stacking pads and respective via interconnects penetrating the insulating layers, each of the pads being positioned between two vertically adjacent ones of the via interconnects, the columnar portions being arranged at a predetermined interval along a first direction for transmitting electromagnetic waves, and
wherein in each of the first post wall and the second post wall, the pads include two or more connecting pads, each of which is arranged in contact with an m-th one of the insulating layers (m is a natural number from 1 to n−1) and connects two or more of the via interconnects arrayed along the first direction in the m-th one of the insulating layers.

2. The interconnect substrate according to claim 1, wherein for the m-th one of the insulating layers, each of the via interconnects is connected to one of the connecting pads.

3. The interconnect substrate according to claim 1, wherein the pads include, for each insulating layer of the first to n−1-th insulating layers, two or more connecting pads each of which is arranged in contact with the insulating layer and connects two or more of the via interconnects arrayed along the first direction in the insulating layer.

4. The interconnect substrate according to claim 3, wherein the connecting pads are arranged in horizontal rows and vertical columns in a cross-sectional view.

5. The interconnect substrate according to claim 4, where for each of the insulating layers, each of the via interconnects is connected to one of the connecting pads.

6. The interconnect substrate according to claim 3, wherein the connecting pads are arranged in a staggered manner in a cross-sectional view.

7. The interconnect substrate according to claim 1, wherein the first to n−1-th insulating layers are alternating first-type insulating layers and second-type insulating layers, each of the first-type insulating layers being a layer in which the via interconnects arrayed along the first direction are all isolated from each other, each of the second-type insulating layers being a layer including the two or more connecting pads.
